(19) United States
(12) Patent Application Publication
(10) Pub. No.: US 2014/0261633 A1
(43) Pub. Date: Sep. 18, 2014

(54) COMPOSITE PHOTOTHERMAL ELECTRIC GENERATING DEVICE

(71) Applicant: CHICONY POWER TECHNOLOGY CO., LTD., New Taipei City (TW)

(72) Inventors: Chao-Jui HUANG, New Taipei City (TW); Ying-Shiang WANG, New Taipei City (TW)

(73) Assignee: CHICONY POWER TECHNOLOGY CO., LTD., New Taipei City (TW)

(21) Appl. No.: 13/846,170

(22) Filed: Mar. 18, 2013

(51) Int. Cl. H01L 31/0525

(52) U.S. Cl. CPC H01L 31/058
USPC 136/248

(57) ABSTRACT

A composite photothermal electric generating device includes a thermal insulation housing, a thermal collecting unit, an electric generating module and a solar panel. The thermal insulation housing includes an opening and is formed with a penetrated hole. The thermal collecting unit is disposed in the thermal insulation housing and arranged corresponding to the location of the opening. At least a portion of the thermal collecting unit is arranged corresponding to the location of the penetrated hole. The electric generating module includes a stirling engine and an electric generator. The stirling engine is adhered to the thermal collecting unit via the penetrated hole. The power of the stirling engine is connected to the electric generator. The solar panel is disposed in the opening, covered and in contact with the thermal collecting unit. Accordingly, the photo energy and the thermal energy of daylight are enabled to be converted into electric energy.

### BACKGROUND OF THE INVENTION

1. Field of the Invention

The present invention relates to an electric generating device, especially to a composite photothermal electric generating device capable of converting photo energy and thermal energy into electric energy.

2. Description of Related Art

The natural resources contained in mother earth are running out, and a resource crisis may occur is the foreseeable further, that is why people are getting more concerned about such issue and have the energy saving concept in minds. For dealing with such issue, besides saving existed energy resource, developing alternative resource is also an important lesson. As such, the daylight which is inexhaustible in supply is the best solution for the alternative resource development.

The daylight can provide photo energy and thermal energy, and skilled people in the art have developed many photoelectric converting devices and thermoelectric converting devices which can be respectively utilized to convert the photo energy and the thermal energy into electric energy. For example, a conventional solar panel is a photoelectric converting device which can be utilized to convert the photo energy provided by daylight into electric energy; for example, the solar powered stirling engine disclosed in the U.S. Pat. No. 4,707,990 is a thermoelectric converting device which utilizes a disc-shaped thermal collector for collecting the thermal energy provided by daylight, and utilizes a stirling engine to convert the thermal energy provided by daylight into electric energy.

The daylight illumination provides both of the photo energy and the thermal energy at the same time, however, the prior art can only convert single type of energy contained in the same amount of daylight (e.g. converting the photo energy into electric energy or converting the thermal energy into electric energy), the photo energy and the thermal energy contained in the same amount of daylight cannot be both converted into electric energy, e.g. a conventional solar panel can only convert the photo energy into electric energy, the temperature of the solar panel is raised after receiving the thermal energy of daylight, but the conventional solar panel is unable to convert the absorbed thermal energy into electric energy, thereby providing a poor energy converting efficiency.

In view of the disadvantages of prior art, the applicant of the present invention has devoted himself for solving the disadvantages mentioned above.

### SUMMARY OF THE INVENTION

The present invention is to provide a composite photothermal electric generating device capable of converting the photo energy and the thermal energy of daylight into electric energy.

Accordingly, the present invention provides a composite photothermal electric generating device which includes a thermal insulation housing, a thermal collecting unit, an electric generating module and a solar panel. The thermal insulation housing is opened, including an opening and formed with a penetrated hole. The thermal collecting unit is disposed in the thermal insulation housing and arranged corresponding to the location of the opening, and at least a portion of the thermal collecting unit is arranged corresponding to the location of the penetrated hole. The electric generating module includes a stirling engine and an electric generator, the stirling engine is adhered to the thermal collecting unit via the penetrated hole, and the power of the stirling engine is connected to the electric generator. The solar panel is disposed in the opening, covered and in contact with the thermal collecting unit.

Preferably, the mentioned composite photothermal electric generating device further includes an inverter electrically connected to the electric generator.

Preferably, the mentioned composite photothermal electric generating device further includes an inverter electrically connected to the solar panel.

Preferably, in the mentioned composite photothermal electric generating device, the stirling engine includes a hot side and a cold side spaced away from the hot side, and the hot side is adhered to the thermal collecting unit.

Preferably, the mentioned composite photothermal electric generating device further includes a thermal dissipating unit disposed at the cold side and thermally connected to the cold side.

Preferably, in the mentioned composite photothermal electric generating device, the thermal dissipating unit includes a thermal dissipating fin set.

Preferably, in the mentioned composite photothermal electric generating device, the thermal collecting unit includes an evacuated solar collector tube.

Preferably, in the mentioned composite photothermal electric generating device, the thermal collecting unit includes a flat plate solar collector, the flat plate solar collector includes a metal coiled pipe, and the metal coiled pipe is in contact with the solar panel.

Preferably, the mentioned composite photothermal electric generating device further includes an optimizer and an inverter, the optimizer is electrically connected to the electric generator, and the inverter is electrically connected to the optimizer.

Preferably, the mentioned composite photothermal electric generating device further includes an optimizer and an inverter, the optimizer is electrically connected to the solar panel, and the inverter is electrically connected to the optimizer.

With the practice of the composite photothermal electric generating device provided by the present invention, the solar panel is utilized to convert the photo energy of daylight into electric energy, and the thermal collecting unit is enabled to drive the stirling engine to drive the electric generator for converting the thermal energy of daylight into electric energy, so the composite photothermal electric generating device provided by the present invention can collect both of the photo energy and the thermal energy contained in the same amount of daylight and convert into electric energy for outputting, thereby effectively improving the disadvantages of prior art.

### BRIEF DESCRIPTION OF DRAWING

FIG. 1 is an exploded view showing the composite photothermal electric generating device according to a first embodiment of the present invention;

FIG. 2 is a perspective view showing the composite photothermal electric generating device according to the first embodiment of the present invention;

FIG. 3 is a cross sectional view showing the composite photothermal electric generating device shown in FIG. 2 according to the first embodiment of the present invention;

FIG. 4 is a perspective view showing the composite photothermal electric generating device according to one alternative of the first embodiment of the present invention;

FIG. 5 is a schematic view showing the composite photothermal electric generating device according to a second embodiment of the present invention;

FIG. 6 is another schematic view showing the composite photothermal electric generating device according to the second embodiment of the present invention;

FIG. 7 is a schematic view showing the composite photothermal electric generating device according to a third embodiment of the present invention; and

FIG. 8 is another schematic view showing the composite photothermal electric generating device according to the third embodiment of the present invention.

### DETAILED DESCRIPTION OF THE INVENTION

Preferred embodiments of the present invention will be described with reference to the drawings.

Please refer to FIG. 1 and FIG. 2, according to one preferred embodiment of the present invention, the composite photothermal electric generating device includes a thermal insulation housing 100, a thermal collecting unit 200, an electric generating module 300 and a solar panel 400. The thermal collecting unit 200 is disposed in the thermal insulation housing 100, and the solar panel 400 is covered and in contact with the thermal collecting unit 200.

According to this embodiment, the thermal insulation housing 100 is substantially formed as a rectangular opened housing which includes an opening 110, and a bottom surface of the thermal insulation housing 100 is formed with a penetrated hole 120.

The thermal collecting unit 200 is disposed in the thermal insulation housing 100 and arranged corresponding to the location of the opening 110, and at least a portion of the thermal collecting unit 200 is arranged corresponding to the location of the penetrated hole 120 of the thermal insulation housing 100. Thermal energy provided by daylight and absorbed by the solar panel 400 is collected by the thermal collecting unit 200 which is in contact with the solar panel 400 via the opening 110. According to this embodiment, the thermal collecting unit can include a flat plate solar collector 210, the flat plate solar collector 210 includes a metal coiled pipe 211, the metal coiled pipe 211 is in contact with the solar panel 400 via the opening 110, the interior of the metal coiled pipe is filled with a working fluid (e.g. water), a pump 212 is installed on the metal coiled pipe 211, and the pump 212 is communicated with the metal coiled pipe 211, thereby the working fluid in the metal coiled pipe 211 being enabled to be driven by the pump 212 for circulatively flowing. In addition, please refer to FIG. 4. The metal coiled pipe 211 is allowed to not be provided with the pump 212.

Please refer to FIG. 1 and FIG. 3. The electric generating module 300 includes a stirling engine 310 and an electric generator 320. According to this embodiment, the stirling engine 310 is preferably to be a low-temperature differential stirling engine (LTD stirling engine), the stirling engine 310 includes a hot side 311 and a cold side 312 spaced away from the hot side 311, and the hot side 311 of the stirling engine 310 is passed the penetrated hole 120 and adhered to the thermal collecting unit 200 thereby being thermally connected to the thermal collecting unit 200; according to this embodiment, the hot side 311 of the stirling engine 300 is preferably to be adhered to at least a portion of the metal coiled pipe 211. The thermal energy collected by the thermal collecting unit 200 is transferred to the stirling engine 310 via the penetrated hole 120 of the thermal insulation housing 100 thereby driving the stirling engine 310 to operate. The cold side 312 of the stirling engine 310 is installed with a thermal dissipating unit 600, and the thermal dissipating unit 600 is thermally connected to the cold side 312 of the stirling engine 310 for performing thermal dissipation to the cold side 312. According to this embodiment, the thermal dissipating unit 600 includes a thermal dissipating fin set 610 thereby increasing the temperature differential between the hot side 311 and the cold side 312 so as to enhance the operating power of the stirling engine 310. In addition, the power provided by the stirling engine 310 is connected to the electric generator 320 for driving the electric generator 320 to generate electricity so as to generate current, the electric generator 320 is capable of generating DC current or AC current, and the electric generator 320 can also be electrically connected to an inverter 510, so the DC current generated by the electric generator 320 can be inverted to AC current through the inverter 510, or the AC current generated by the electric generator can be inverted to DC current through the inverter 510.

The solar panel 400 is disposed in the opening 110, and preferably covered the thermal collecting unit 200. One surface of the solar panel 400 is defined as a receiving surface 410, the receiving surface 410 is oriented to face the exterior of the thermal insulation housing 100, the solar panel 400 utilizes the receiving surface 410 to absorb the photo energy (preferably from the daylight) and the absorbed photo energy is inverted to DC current, and preferably, the solar panel 400 is electrically connected an inverter 520, so the DC current can be inverted to AC current through the inverter 520. Preferably, the electric generator 520 and the solar panel 400 can be electrically connected to the same inverter 510 (520), so the DC current generated by the electric generator 320 and the solar panel 400 can be inverted to AC current through the same inverter 510 (520).

Please refer to FIG. 4 and FIG. 5. The current generated by the electric generating module 300 is allowed to pass an optimizer 530 for stabling the current then to pass the inverter 510. The current generated by the solar panel 400 is also allowed to pass an optimizer 540 for stabling the current then to pass the inverter 520. Preferably, the current generated by the electric generating module 300 and the solar panel 400 is allowed to pass the same optimizer 530 (540) then to pass the inverter 510 (520). Please refer to FIG. 5, which discloses the composite photothermal electric generating device according to a second embodiment of the present invention. The structure provided by the second embodiment is substantially the same as the structure disclosed in the first embodiment, and the same feature and structure will not be illustrated hereinafter. The difference between this embodiment and the first embodiment is that the thermal collecting unit 200 can include plural evacuated solar collector tubes 220 arranged in parallel, the evacuated solar collector tubes 220 are in contact with the solar panel 400 via the opening 110 and one end of each of the evacuated solar collector tubes 220 is respectively disposed in a water tank 230 and in contact with the working fluid (e.g. water) filled in the water tank 230, the evacuated solar collector tubes 220 absorb the thermal energy of daylight via the opening 110, and the adsorbed thermal energy is transferred to the working fluid in the water tank 230. The hot side 311 of the stirling engine 310 is adhered to an outer wall of the water tank 230, so the thermal energy contained in the working fluid can be transferred via the penetrated hole 120 to the stirling engine 310 thereby driving the stirling engine 310 to operate. As such, the stirling engine 310 is enabled to further drive the electric generator 320 to generate current.

Please refer to FIG. 7 and FIG. 8, which disclose the composite photothermal electric generating device according to a third embodiment of the present invention. The structure provided by the third embodiment is substantially the same as the structure disclosed in the first embodiment, and the same feature and structure will not be illustrated hereinafter. The difference between this embodiment and the first embodiment is that the thermal collecting unit 200 can include plural evacuated solar collector tubes 220 arranged in a fan-like manner, the evacuated solar collector tubes 220 are in contact with the solar panel 400 via the opening 110, and one end of each of the evacuated solar collector tubes 220 which are arranged close to each other is adhered to the hot side 311 of the stirling engine 310. Thermal energy of daylight is absorbed by the evacuated solar collector tubes 220 via the opening 110, and the absorbed thermal energy is transferred via the penetrated hole 120 to the stirling engine 310 thereby driving the stirling engine 310 to operate, and the stirling engine 310 is enabled to further drive the electric generator 320 to generate current.

With the practice of the composite photothermal electric generating device provided by the present invention, the solar panel 400 can be utilized to convert the photo energy of daylight into electric energy, and the thermal collecting unit 200 is enabled to drive the stirling engine 310 to drive the electric generator 320 for converting the thermal energy of daylight into electric energy, so the composite photothermal electric generating device provided by the present invention can collect both of the photo energy and the thermal energy contained in the same amount of daylight and convert into electric energy for outputting, thereby effectively improving the disadvantages of prior art.

Although the present invention has been described with reference to the foregoing preferred embodiments, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A composite photothermal electric generating device, comprising:
a thermal insulation housing, including an opening and the thermal insulation housing is formed with a penetrated hole;
a thermal collecting unit, disposed in the thermal insulation housing and arranged corresponding to the location of the opening, wherein at least a portion of the thermal collecting unit is arranged corresponding to the location of the penetrated hole;
an electric generating module, including a stirling engine and an electric generator, wherein the stirling engine is adhered to the thermal collecting unit via the penetrated hole, and the power of the stirling engine is connected to the electric generator; and
a solar panel, disposed in the opening, wherein the solar panel is covered and in contact with the thermal collecting unit.

2. The composite photothermal electric generating device according to claim 1, further including an inverter, wherein the inverter is electrically connected to the electric generator.

3. The composite photothermal electric generating device according to claim 1, further including an inverter, wherein the inverter is electrically connected to the solar panel.

4. The composite photothermal electric generating device according to claim 1, wherein the stirling engine includes a hot side and a cold side spaced away from the hot side, and the hot side is adhered to the thermal collecting unit.

5. The composite photothermal electric generating device according to claim 4, further including a thermal dissipating unit, wherein the heat dissipating unit is disposed at the cold side and thermally connected to the cold side.

6. The composite photothermal electric generating device according to claim 5, wherein the thermal dissipating unit includes a thermal dissipating fin set.

7. The composite photothermal electric generating device according to claim 1, wherein the thermal collecting unit includes an evacuated solar collector tube.

8. The composite photothermal electric generating device according to claim 1, wherein the thermal collecting unit includes a flat plate solar collector, the flat plate solar collector includes a metal coiled pipe, and the metal coiled pipe is in contact with the solar panel.

9. The composite photothermal electric generating device according to claim 1, further including an optimizer and an inverter, wherein the optimizer is electrically connected to the electric generator, the inverter is electrically connected to the optimizer.

10. The composite photothermal electric generating device according to claim 1, further including an optimizer and an inverter, wherein the optimizer is electrically connected to the solar panel, the inverter is electrically connected to the optimizer.
